(19) United States
(12) Patent Application Publication
(10) Pub. No.: US 2012/0216954 A1
(43) Pub. Date: Aug. 30, 2012

(54) APPARATUS AND METHOD FOR FABRICATING SEMICONDUCTOR DEVICES AND SUBSTRATES

(76) Inventors: Jin-ho PARK, Yongin-si (KR); Seong-hwee Cheong, Seoul (KR); Gil-heyun Choi, Seoul (KR); Sang-woo Lee, Seoul (KR); Ho-ki Lee, Seongnam-si (KR)

(21) Appl. No.: 13/459,275

(22) Filed: Apr. 30, 2012

Related U.S. Application Data
(62) Division of application No. 12/007,517, filed on Jan. 11, 2008, now abandoned.

(30) Foreign Application Priority Data
Jan. 12, 2007 (KR) 10-2007-0003955

(51) Int. Cl. H01L 21/306; C23C 16/455

(52) U.S. Cl. 156/345.34; 118/724

(57) ABSTRACT

An apparatus and method for fabricating semiconductor devices may increase reliability of the semiconductor devices by decreasing generation of particles and enhancing operation efficiency by decreasing the number of cleanings. The apparatus may include a chamber having a cover plate, susceptors for securely placing semiconductor substrates within the chamber, shower heads located on the cover plate to supply reaction gases into the chamber, and a curtain gas line connected to the cover plate to supply heated curtain gases between the shower heads.

### PRIORITY STATEMENT

This is a Divisional Application of application Ser. No. 12/007,517, filed Jan. 11, 2008, which claims priority under 35 U.S.C. §119 to Korean Patent Application No. 10-2007-0003955, filed on Jan. 12, 2007, in the Korean Intellectual Property Office, the entire contents of which are incorporated herein by reference.

### BACKGROUND

1. Field

Example embodiments relate to an apparatus for fabricating semiconductor devices and a method of using the same, and more particularly to an apparatus for fabricating semiconductor devices and a method of using the same to process semiconductor substrates.

2. Description of the Related Art

An apparatus for fabricating semiconductor devices may be employed when depositing a thin film on a semiconductor substrate or etching the thin film. For example, reaction gases may be introduced into a chamber and reacted with each other to thereby form the thin films on the semiconductor substrates. The reaction gases may be consistently supplied over the semiconductor substrates through a shower head. A plurality of holes for supplying the reaction gases may be regularly disposed in the shower head.

Generally, however, a periphery of the shower head may be cooler than a center thereof. Therefore, the reaction gases sprayed onto a periphery of a shower head may be relatively cool and may be left as residues around the periphery of the shower head without being volatilized. Such residues may be a particle source on the semiconductor substrate and degrade reliability of the semiconductor device.

Such residues may be eliminated by dry and wet cleaning of the chamber and the shower head. However, as the quantity of the residues is increased, a cleaning cycle of the chamber and the shower head is decreased. Wet cleaning may be performed by an operator after opening the chamber that may be manipulated so that the apparatus for fabricating the semiconductor devices may not be used during the cleaning. As a result, an operation efficiency of the apparatus for fabricating the semiconductor devices may be degraded.

### SUMMARY

Example embodiments provide an apparatus for fabricating semiconductor devices, which may decrease generation of particles to enhance reliability of the semiconductor devices and decreases the number of cleanings to increase operation efficiency.

Example embodiments also provide a method of processing semiconductor substrates, which may decrease generation of particles and the number of cleanings to increase operation efficiency.

According to an example embodiment, there may be provided an apparatus for fabricating a semiconductor device comprising: a chamber including a cover plate; a plurality of susceptors for securely placing semiconductor substrates within the chamber; a plurality of shower heads located on the cover plate to supply reaction gases into the chamber; and a curtain gas line connected to the cover plate to supply heated curtain gases between the plurality of shower heads.

The apparatus may further comprise a first heating member located to the curtain gas line to heat the curtain gases. Furthermore, the plurality of shower heads may further comprise internal second heat members.

According to another example embodiment, there may be provided an apparatus for fabricating a semiconductor device including a chamber including a cover plate, a plurality of susceptors for securely placing semiconductor substrates within the chamber, a plurality of shower heads located on the cover plate to supply reaction gases into the chamber, and a circulation liquid line for making heated liquid circulate within the plurality of shower heads to heat the plurality of shower heads.

The circulation liquid line may be located to circulate peripheries of the plurality of shower heads. Moreover, liquid circulated through the circulation liquid line may comprise an anti-freezing solution.

According to another example embodiment, there may be provided a method of processing semiconductor substrates including loading semiconductor substrates on a plurality of susceptors within a chamber, supplying curtain gases between a plurality of shower heads located to a cover plate of the chamber, heating peripheries of the plurality of shower heads, and supplying reaction gases into the chamber via the plurality of shower heads.

The heating of the peripheries of the plurality of shower heads may comprise supplying the curtain gases heated by using a first heating member, using second heating members installed within the plurality of shower heads, or making heated liquid circulate within the plurality of shower heads.

### BRIEF DESCRIPTION OF THE DRAWINGS

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 is a sectional view illustrating an apparatus for fabricating semiconductor devices according an example embodiment.

FIG. 2 is a bottom side view illustrating a cover plate of the apparatus for fabricating the semiconductor devices of FIG. 1.

FIG. 3 is a sectional view illustrating an apparatus for fabricating semiconductor devices according to another example embodiment.

FIG. 4 is a bottom side view illustrating a cover plate of the apparatus for fabricating the semiconductor devices of FIG. 2.

FIG. 5 is a graph illustrating a thickness variation of a tungsten nitride (WN) thin film and the number of particles resulting from the number of accumulated wafers according to experiments of an example embodiment.

### DETAILED DESCRIPTION OF EXAMPLE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Example embodiments will now be described more fully with reference to the accompanying drawings. Example embodiments may, however, be embodied in many different forms and should not be construed as being limited to the embodiments set forth herein; rather, these embodiments may be provided so that this disclosure will be thorough and complete, and will fully convey the concept of the example embodiment to those skilled in the art. In the drawings, the thicknesses of layers and regions are exaggerated for clarity.

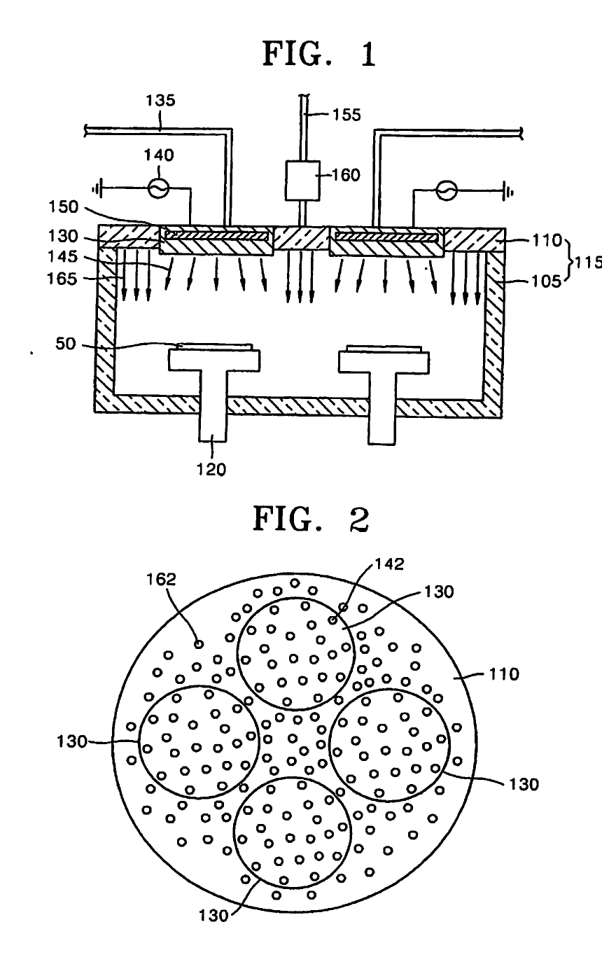

FIG. 1 is a sectional view illustrating an apparatus for fabricating semiconductor devices according an example embodiment, and FIG. 2 is a bottom side view illustrating a cover plate of the apparatus for fabricating the semiconductor devices of FIG. 1.

Referring to FIGS. 1 and 2, a chamber 115 may include a body 105 and a cover plate 110. The body 105 may be connected to a vacuum line (not shown) to make an inside of the chamber 115 in a vacuum state. For example, an inner space of the chamber 115 may be open or closed by the cover plate 110. The shape of the chamber 115 and the cover plate 110 are illustrative and need not be as shown. For example, the cover plate 110 may be shaped as a dome.

A plurality of susceptors 120 may place semiconductor substrates 50 within the chamber 115. For example, the susceptors 120 may extend outside the chamber 115 and may be moved up and down. The susceptors 120 may be arranged as stages or stations. The number of susceptors 120 may be appropriately selected by one of ordinary skilled in the art, and need not limit the scope of example embodiments.

Shower heads 130 may be disposed over the susceptors 120 to supply reaction gases 145 into the inside of the chamber 115. For example, the shower heads 130 may be fixed to the cover plate 110 and be separated from each other by a predetermined or desired distance. The number of shower heads 130 may be illustratively shown, and need not limit the scope of example embodiments.

For example, the reaction gases 145 may be sprayed from each of the shower heads 130, and then supplied to the inside of the chamber 115. The reaction gases 145 may be supplied to respective shower heads 130 through reaction gas lines 135. Each of the shower heads 130 may include a plurality of holes 142 connected to the reaction gas lines 135. Accordingly, the reaction gases 145 may be sprayed into the inside of the chamber 115 via the holes 142 in the inside of the shower heads 130. The reaction gases 145 may be heated at a predetermined or desired temperature and supplied to the chamber 115.

Optionally, an electrical power source 140 may be connected to the shower heads 130 to form a plasma of the reaction gases 145 within the chamber 115. The location of the electrical power source 140 may be diversely modified, and need not limit the scope of example embodiments.

Curtain gases 165 may be supplied between the shower heads 130. For example, the curtain gases 165 may be supplied to the cover plate 110 through a curtain gas line 155. The curtain gas line 155 may be connected to the cover plate 110, and the cover plate 110 may include a plurality of holes 162 in portions between the shower heads 130. Thus, the curtain gases 165 may be supplied between the shower heads 130 from the curtain gas line 155 through the holes 162.

The curtain gases 165 may separate the reaction gases 145 from each other. Therefore, the curtain gas 165 may be inert gases or reductive gases. For example, the curtain gas 165 may include nitrogen, argon and/or hydrogen. The curtain gases 165 may be heated by a first heating member 160 attached to the curtain gas line 155. The heated curtain gases 165 may heat the peripheries of the shower heads 130. Unless the curtain gases 165 are heated, a temperature at the peripheries of the shower heads 130 may be lower than that of the center.

Therefore, the heated curtain gases 165 assist to more consistently maintain the temperature of the shower heads 130. Thus, residues of the reaction gases 145 which cannot be volatilized but are left on the periphery of the shower heads 130 may be reduced or prevented. Accordingly, a cleaning cycle of the chamber 115 and the shower heads 130 may be longer than the conventional cleaning cycle. Moreover, the residues may be decreased to reduce the probability of a particles (not shown) dropping on the semiconductor substrate 50. Consequently, the reliability of the semiconductor devices fabricated using the semiconductor substrates 50 may be increased.

Optionally, each of the shower heads 130 may further include a second heating member 150. The second heating members 150 may heat the shower heads 130 at an equal temperature to consistently maintain the temperature of the reaction gases 145. For example, the second heating members 150 may have a multi-zone that heats a first portion provided along the periphery of the shower head 130 to be higher than a second portion provided in the center of the shower head 130. That is to say, the second heating member 150 may be more concentrated around the periphery of the shower head 130, as compared to the center of the shower head 130.

For example, the first heating member 160 and the second heating members 150 may include a heating line or a heat exchanger. The shower heads 130 may be needed to be heated at a proper temperature depending on the type of reaction gases 145.

Therefore, the second heating members 150 may contribute to make the temperature of the shower heads 130 more consistent. However, the second heating members 150 may be omitted when suitably adjusting the temperature of the curtain gases 165.

Table 1 displays temperatures at the periphery of shower heads 130 when the shower heads 130 were not heated (a comparative example) or where heated (an experimental example) without heating the curtain gases 165. In the comparative example and the experimental example, the centers of the shower heads 130 were maintained at about 90° C. In Table 1, SH1, SH2, SH3 and SH4 denote any one of the shower heads 130, respectively.

TABLE 1

| | SH1 | SH2 | SH3 | SH4 |
|---|---|---|---|---|
| Comparative example | 68.4° C. | 75.4° C. | 76.4° C. | 71.5° C. |
| Experimental example | 89.5° C. | 93.5° C. | 94.2° C. | 91.5° C. |

Referring to Table 1, a temperature difference between the centers and the peripheries of the shower heads 130 reached approximately 20° C. in the comparative example. This is because the curtain gases 165 cool the peripheries of the shower heads 130. However, the temperature difference at the center and the periphery of the shower head 130 was within 5° C. in the experimental example. Therefore, according to the experimental example, the temperature of the shower heads 130 may be more consistently maintained.

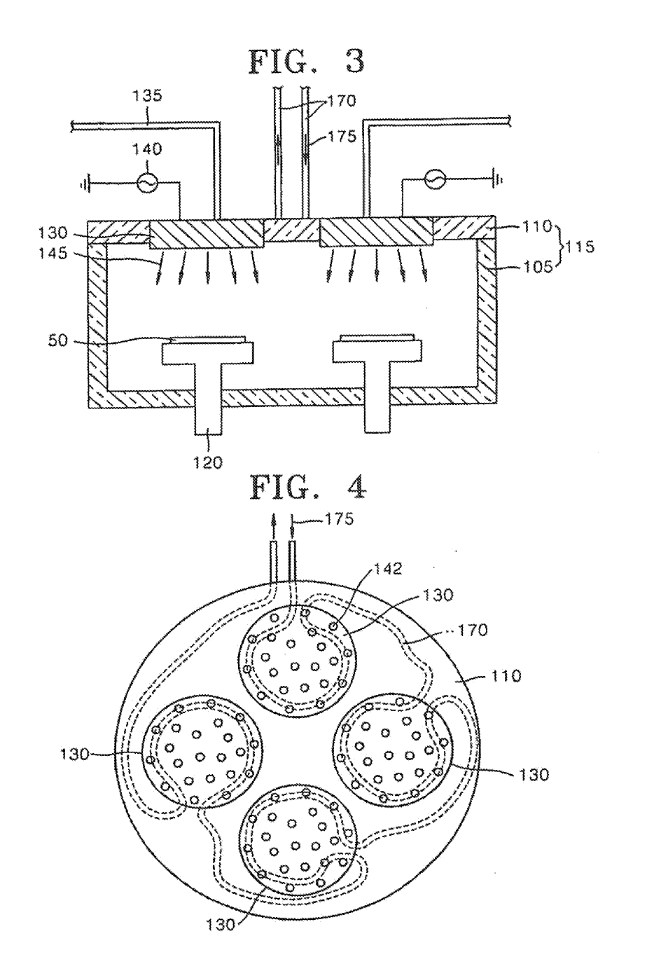

FIG. 3 is a sectional view illustrating an apparatus for fabricating semiconductor devices according to another example embodiment. FIG. 4 is a bottom side view illustrating a cover plate of the apparatus for fabricating the semiconductor devices of FIG. 2. The apparatus for fabricating the semiconductor devices according to example embodiments is obtained by partially modifying a structure of the apparatus illustrated in FIGS. 1 and 2. Like reference numerals in the drawings denote like elements, and thus their description may not be repeated.

Referring to FIGS. 3 and 4, a temperature of shower heads 130 may be controllable using a heated liquid 175. The liquid 175 may be circulated via a circulation liquid line 170. For example, a circulation liquid line 170 may be placed to circulate peripheries of the shower heads 130. The circulation liquid line 170 may be circulated the insides of the shower heads 130 and connected via a cover plate 110. Thus, there may be no need to separately provide the circulation liquid line 170 to each shower head 130.

For example, the liquid 175 may include an anti-freezing solution. For example, the anti-freezing solution may include calcium chloride, magnesium chloride, ethylene glycol and/or ethyl alcohol. Ethylene glycol has a high melting point at about 197° C.

For example, when tungsten nitride (WN) films are formed on semiconductor substrates 50, the shower heads 130 must be heated within a range of 80˜100° C. To meet this demand, the anti-freezing solution may be heated within a range of 100˜125° C. Unlike water, the anti-freezing solution has an advantage of being heated at 100° C. and higher.

Therefore, the heated liquid 175 may be used to raise the temperature of the peripheries of the shower heads 130 at a relatively low temperature, so that the temperature of the shower heads 130 may be constantly maintained. Accordingly, the temperature of the reaction gases 145 sprayed from the peripheries of the shower heads 130 may be increased, and thereby, the problem of the reaction gases unvolatized but left on the peripheries of the shower heads 130 may be reduced or prevented.

According to another example embodiment, the structures of FIGS. 1 and 3 may be combined. Thus, the heated curtain gases 165 may be supplied between the shower heads 130 and, simultaneously, the circulation liquid line 170 may be located within the shower heads 130. Furthermore, the second heating members 150 may be further formed within the shower heads 130.

Hereinafter, a method of processing semiconductor substrates according to an example embodiment will be described. The current method may be carried out using the above-stated apparatus for fabricating the semiconductor devices according to an example embodiment.

Referring to FIGS. 1 and 2, the semiconductor substrates 50 may be loaded on the susceptors 120 within the chamber 115. The curtain gases 165 may be supplied between the shower heads 130 of the chamber 115, and the peripheries of the shower heads 130 may be heated. Then, the reaction gases 145 may be supplied into the chamber 115 via the shower heads 130.

The reaction gases 145 may be used to form thin films on the semiconductor substrates 50, or etch the thin films or the semiconductor substrates 150. For example, the reaction gases 145 may partially include a tungsten source gas such as WF₆, W(CO)₆ or WCl₆ and a reduction gas such as NH₃, H₂, B₂H₆, SiH₄ or S₂H₆, and, in this case, a tungsten nitride film may be formed on the semiconductor substrate 50.

For example, the peripheries of the shower heads 130 may be heated by supplying the heated curtain gases 165 between the shower heads 130. Alternatively, the peripheries of the shower heads 130 may be heated by the second heating members 150.

In another example embodiment, as illustrated in FIGS. 3 and 4, the peripheries of the shower heads 130 may be heated by circulating the heated liquid 175 within the shower heads 130. In case of the above-mentioned deposition of the tungsten nitride thin film, the liquid 175 may include the anti-freezing solution heated at a range from 100˜125° C. as illustrated in FIGS. 1 and 2.

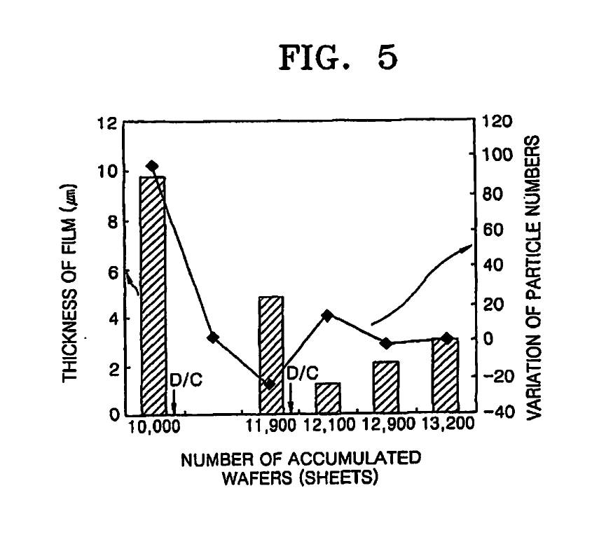

FIG. 5 is a graph plot illustrating a thickness variation of a tungsten nitride (WN) thin film and the number of particles resulting from the number of accumulated wafers according to the experimental example, listed in Table 1. The experimental example involves shower heads heated around their periphery, but without the use of heated curtain gases. In FIG. 5, the thickness of depositing the thin film was measured in a wall of the chamber (115 of FIG. 1), and a wafer composed of silicon was used as the semiconductor substrate. The variation of the number of particles was measured at a dimension of 0.065 μm before and after depositing the tungsten nitride thin film.

Referring to FIG. 5, when the number of the accumulated wafers reached roughly 10,000 sheets, the number of the particles was increased by roughly 100 percent. However, the number of particles was returned to nearly zero solely by the dry cleaning (D/C), without opening the chamber (115 of FIG. 1) for wet cleaning. Therefore, by adequately adding dry cleaning (D/C), the number of the particles was decreased to roughly 20 percent or fewer.

The result of repeated experiments indicated that the number of particles was not greatly increased, as dry cleaning was performed roughly at every 5,000 sheet intervals. Wet cleaning by opening the chamber (115 of FIG. 1) could be omitted until the wafers reached about 40,000 sheets. Compared to this result, dry cleaning and wet cleaning were conventionally performed whenever the number of wafers was reached by roughly 200 sheets. According to example embodiments, the cleaning cycle of the chamber (115 of FIG. 1) and the shower heads (130 of FIG. 1) may be greatly increased over the conventional cleaning cycle, which may greatly increase an operation efficiency of the apparatus for fabricating the semiconductor devices.

In an apparatus for fabricating the semiconductor devices according to an example embodiment, temperatures at centers and peripheries of the shower heads may be more consistently maintained. Thus, particles within a chamber that may be generated due to un-volatized reaction gases remaining after being sprayed by shower heads, may be decreased. The decrease in the number of particles may increase reliability of the semiconductor devices being fabricated using the apparatus.

Moreover, the decreased number of particles may increase the cleaning cycle of the apparatus for fabricating the semiconductor devices. Therefore, an operation efficiency of the apparatus for fabricating the semiconductor devices may be increased.

While example embodiments have been particularly shown and described, it will be understood by those of ordinary skill in the art that various changes in form and details may be made therein without departing from the spirit and scope of example embodiments as defined by the following claims.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. An apparatus for fabricating a semiconductor device comprising:
a chamber including a cover plate;
a plurality of susceptors for placing semiconductor substrates within the chamber;
a plurality of shower heads on the cover plate to supply reaction gases into the chamber; and
at least one circulation liquid line for circulating heated liquid within the plurality of shower heads to heat the plurality of shower heads.

2. The apparatus of claim 1, wherein the at least one circulation liquid line is located to circulate heated liquid at the peripheries of the plurality of shower heads.

3. The apparatus of claim 2, wherein the at least one circulation liquid line is connected to the cover plate to supply the heated liquid to the plurality of shower heads.

4. The apparatus of claim 1, wherein liquid circulated through the circulation liquid line comprises an anti-freezing solution.

5. The apparatus of claim 4, wherein the anti-freezing solution is heated at a temperature range of 100˜125° C.

6. The apparatus of claim 1, further comprising:
at least one curtain gas line connected to the cover plate to supply curtain gases between the plurality of shower heads or around the peripheries of the shower heads.
